(19) United States
(12) Patent Application Publication
(10) Pub. No.: US 2008/0142813 A1
(43) Pub. Date: Jun. 19, 2008

(54) LED and method for making the same

(75) Inventors: Hsiao-Kuo Chang, Taoyuan City (TW); Chih-Peng Chen, Taipei City (TW); Chih-Wei Hsu, Lujhu Township (TW)

Correspondence Address: BACON & THOMAS, PLLC, 625 SLATERS LANE, FOURTH FLOOR, ALEXANDRIA, VA, 22314, US

(73) Assignee: Kinik Company, Taipei (TW)

(21) Appl. No.: 11/984,137

(22) Filed: Nov. 14, 2007

(30) Foreign Application Priority Data
Dec. 15, 2006 (TW) 095147086

(51) Int. Cl. H01L 33/00

(52) U.S. Cl. 257/77; 438/45; 257/E33.013

(57) ABSTRACT

A light emitting diode device and a method for manufacturing the same are disclosed. The method comprises following steps: (A) providing a substrate; (B) forming a diamond layer on the surface of the substrate; (C) forming a doping region on the upper surface of the diamond layer; (D) bonding a semiconductor epitaxy layer on the upper surface of the diamond layer; and (E) removing the substrate. Accordingly, owing to the absence of an adhesion layer necessary for a conventional LED, the LED of the present invention can reduce the blockage for heat transfer caused by a resin adhesion layer and light obscuration caused by a metal adhesion layer so as to enhance the efficiency of heat dissipation of LEDs, simplify the process, and enhance the performance and the stability of products.

### BACKGROUND OF THE INVENTION

1. Field of the Invention

The present invention related to a light emitting diode device and the manufacturing method thereof and, more particularly, to a light emitting diode device with improved heat dissipation, high light emitting efficiency, and high light emitting stability, and the manufacturing method thereof.

2. Description of Related Art

The light emitting diode device (LED) has been commercialized and applied since the 1960s. Because of their high anti-shock, long lifetime, and low power consumption, the LEDs are widely applied in many electrical devices in our daily life, such as in indicating signs and light sources.

In recent years, due to the rapid development of colorfulness and high brightness of modern LEDs, the application of LEDs is extended to the outdoor application, e.g. outdoor displays, and traffic signals. However, the blue light LEDs only improved very slowly until Nichia Inc. disclosed blue/white light LEDs made of GaN in 1993. The blue light LED of GaN is now made by forming a poly-crystal AlN thin film or a single-crystal AlN thin film (functioning as a buffer layer) on the sapphire wafer, and growing gallium nitride (GaN) on the buffer layer in sequence. Since the GaN grown on the buffer layer illustrated above has very good quality, the efficiency and the stability of the light emission can be significantly improved.

However, heat dissipation is still a big problem in the application of the LEDs. If the heat generated from the LEDs cannot be suitably dissipated, the working temperature of the LEDs will increase that results in the decreasing of the brightness and the lifetime of LEDs. Hence, the reduction of the heat accumulation is still an important target for the application of LEDs in the field of backlight modules and display devices.

To improve the heat dissipation of the LED, replacement of the material, or that of the structure of the LED in the manufacturing process is required. So far, replacements of the material of the substrate, or flip-chip mounting instead of naked chip mounting are the main ways for improving the heat dissipation of LEDs. Among these methods for improving heat dissipation, some researchers suggested using diamond to replace the sapphire substrate because the high thermal conductivity of diamond may increase the efficiency of heat dissipation of the LEDs. However, even though the lattice matching of the diamond and the gallium nitride is superior to that of the gallium nitride and the sapphire substrate, it is difficult to epitaxial grow a single crystal gallium nitride layer on the surface of diamond. So far, the difficulty is reduced somewhat by forming a buffer layer on the surface of the diamond. In addition, the difficulty can also be overcome by wafer bonding technology that bonding the diamond layer and the epitaxy layer through an additional adhesion layer deposited therebetween. Nevertheless, both the buffer layer and adhesion layer will affect the heat dissipation of the LEDs.

A method for manufacturing LEDs by bonding an epitaxy layer and a substrate with high heat conductive coefficient (e.g. Si, Al, Cu, Ag, SiC, diamond, or graphite) through two-step transfer process is disclosed in TW5733373. The method is achieved by the following steps: providing a temporary connecting substrate, with an epitaxy layer thereon instead of a conventional substrate with epitaxy at first; forming a permanently bonded alloy (e.g. In, or Au) layer by bonding a second connecting layer on an etch-stop layer of the epitaxy layer and a third connecting layer of the substrate with high heat conductive coefficient together; and removing the temporary connecting substrate. Through the steps illustrated above, an LED that has better stability and high light emitting efficiency, and combines with an epitaxy layer and a substrate with high heat conductive coefficient, and an ohmic layer on the top thereof is manufactured.

In addition, TWI223899 disclosed another LED structure. The LED at least comprises: a conductive layer (e.g. metal or non-metal) for transferring the heat generated from the LED, a reflecting layer on the conductive layer; and an epitaxy structure formed on the conductive layer having the reflecting layer by means of heat conductive glues (e.g. silicone resin or epoxy resin). The epitaxy structure includes multiple III-V compound semiconductor epitaxy layers. These III-V compound semiconductor epitaxy layers comprise at least a first electric semiconductor layer, an active layer, and a second semiconductor layer. When the current is applied, the disclosed LED emits light.

FIGS. 1A to 1D show the cross-section views of an LED having a metal adhesion layer, a semiconductor epitaxy layer, and a substrate in a conventional manufacturing method. As shown in FIG. 1A, a substrate 10 is first provided. Then, as shown in FIG. 1B, a metal layer 11 is formed on the surface of the substrate 10. A semiconductor epitaxy layer 12 is formed on the surface of the metal layer 11 through high temperature laminating, as show in FIG. 1C. The semiconductor epitaxy layer 12 includes a first semiconductor layer 121, an active layer 122, and a second semiconductor layer 123 in sequence. Finally, as shown in FIG. 1D, the second semiconductor layer 123 and the active layer 122 are partially removed to expose the first semiconductor layer 121 therebelow. Subsequently, a first electrode 13 is formed on the surface of the second semiconductor layer 123, and a second electrode 14 is formed on the surface of the first semiconductor layer 121.

As illustrated above, the manufacturing of the lateral LED, as shown in FIG. 1D, can be completed. Even though a diamond layer with high heat conductivity is applied as a substrate or a heat conduction substrate in the conventional LED to increase heat dissipation efficiency, the metal layer 11 between the substrate 10 and the semiconductor epitaxy layer 12 are still a barrier for light emission and heat transfer. Hence, both the efficiency of light emission and the heat transferring of the LED are decreased. Moreover, the conventional manufacturing method illustrated above is still very complicated. Therefore, there is an unfulfilled need for a method of simplifying the manufacturing process, and improving the heat dissipation of the LED.

### SUMMARY OF THE INVENTION

The object of the present invention is to provide a method for manufacturing a light emitting diode device, which comprises the following steps:

(A) providing a substrate;

(B) forming a diamond layer on the surface of the substrate;

(C) forming a doping region on the upper surface of the diamond layer;

(D) bonding a semiconductor epitaxy layer on the upper surface of the diamond layer, wherein the semiconductor epitaxy layer comprises a first semiconductor layer, an active layer, and a second semiconductor layer; and

(E) removing the substrate.

Accordingly, the present invention provides a light emitting diode device, which comprises a diamond layer and a semiconductor epitaxy layer. The upper surface of the diamond layer has a doping region formed thereon, and the semiconductor epitaxy layer is formed on the upper surface of the diamond. The semiconductor layer comprises a first semiconductor layer, an active layer, and a second semiconductor layer.

In the manufacturing method of the present invention, the wafer bonding process is performed for bonding the diamond layer and the semiconductor epitaxy layer through the doping region on the upper surface of the diamond layer. Accordingly, the semiconductor epitaxy layer can be bonded on the diamond layer in the absence of an adhesion layer necessary for a conventional LED so as to simplify the process.

In addition, the light emitting diode device of the present invention can enhance the efficiency of heat dissipation due to the presence of the diamond layer with high thermal conductivity, and inhibit light obscuration caused by a metal adhesion layer so as to enhance the efficiency of heat dissipation of LEDs.

The manufacturing method of the present invention can further comprise step (F) forming a metal layer on the lower surface of the diamond layer, and forming a first electrode on the surface of the semiconductor epitaxy layer. Accordingly, the present invention provides a vertical LED, herein the metal layer on the lower surface of the diamond layer functions as a reflector and an electrode.

The vertical LED of the present invention can enhance light extraction so as to improve the luminescence efficiency, performance and stability of products.

The present invention further provides a method for manufacturing a lateral LED, which comprises aforementioned steps (A) to (F), and step (G) removing part of the second semiconductor layer and the active layer to expose the first semiconductor layer therebelow, and forming a second electrode on the surface of the first semiconductor layer after step (F). Herein, the material of the diamond layer can be an insulated diamond or a conductive diamond, and the metal layer on the lower surface of the diamond layer can be as a reflector.

Alternatively, the method for manufacturing a lateral LED can comprise the aforementioned steps (A) to (F), and in step (F), before the first electrode is formed on the surface of the semiconductor epitaxy layer, parts of the second semiconductor layer and the active layer are removed to expose the first semiconductor layer therebelow, and a second electrode is formed on the surface of the first semiconductor layer.

In the manufacturing method of the present invention, the process for forming the diamond in step (B) can be performed by chemical vapor deposition (e.g. Hot-filament Chemical Vapor Deposition, Microwave Assisted Chemical Vapor Deposition, or other equivalent methods), or physical vapor deposition (e.g. Cathodic Arc Evaporation, Ion-Beam Spattering, Evaporation, Laser Ablation, DC Sputtering, or other equivalent methods).

In the manufacturing method of the present invention, the process for forming the doping region in step (C) can be performed by ion implantation to speed up ions until the ions exhibit enough energy and speed so that the ions can be implanted in the diamond layer and located at a predetermined depth. Herein, the depth of ion implantation depends on the energy of the ion-beam. In addition, plasma immersion ion implantation also can be used.

In the manufacturing method of the present invention, the process for forming the semiconductor epitaxy layer in step (D) can be performed by metal organic chemical vapor deposition, molecular beam epitaxy, liquid phase epitaxy, vapor phase epitaxy, or other equivalent methods.

In the manufacturing method of the present invention, the process for bonding a semiconductor epitaxy layer on the upper surface of the diamond layer in step (D) can be performed by high temperature bonding. Herein, the bonding temperature depends on the type of dopant. In general, the bonding temperature is between 300˜1000° C.

In the manufacturing method of the present invention, the process for removing the substrate, partially removing the second semiconductor layer and the active layer can be performed by etching (e.g. wet etching or dry etching) or grinding (e.g. physical cutting, chemical cutting, or other equivalent methods).

In the manufacturing method of the present invention, the process for forming the metal layer, the first electrode, and the second electrode can be performed by physical vapor deposition (e.g. Thermal Evaporation, Electronic Beam Assisted Exaporation, Ion-Beam Sputtering, Plasma Sputtering, or other equivalent methods), or chemical vapor deposition.

The substrate used in the present invention can be a silicon substrate, or a SiC substrate. In the semiconductor epitaxy layer, the electrical property of the first semiconductor layer is different from that of the second semiconductor layer, and the first semiconductor layer and the second semiconductor layer are made of binary, ternary or quaternary doping semiconductor. In detail, the first semiconductor layer is an N-type doping semiconductor layer, while the second semiconductor layer is a P-type doping semiconductor layer; and the first semiconductor layer is a P-type doping semiconductor layer, while the second semiconductor layer is an N-type doping semiconductor layer.

The aforementioned doping region comprises at least one element selected from the group consisting of elements of group II, elements of group III, elements of group IV, and elements of group V, and the element can react with diamond and exists in the semiconductor epitaxy layer, such as N, P, B, Al, or other equivalent elements.

The material of the diamond layer of the present invention can be selected from the group consisting of diamond, diamond-like carbon and nano diamond. Herein, the diamond layer can be a conductive or insulation single-crystal diamond film, poly-crystal diamond film, or amorphous diamond film. The material of the diamond layer used in a vertical LED is a conductive diamond, and that used in a lateral LED can be a conductive diamond or an insulated diamond. The materials of the first electrode, the second electrode, and the metal layer used in the present invention are not limited and can be selected from the group consisting of Al, W, Cr, Cu, Ti, Sn, Ni, Mo, Pt, Au, Ag, Be alloy, Ge alloy, Sn alloy, TiN, Al alloy and Cr alloy.

In the vertical LED using the conductive diamond layer, the metal layer can function as an electrode and a reflector. In the lateral LED, the material of the diamond layer can be a conductive diamond or insulated diamond, and the metal layer on the lower surface of the diamond layer can be as a reflector and the ohmic contact is not necessary for the metal layer.

The lateral LED of the present invention can be disposed on a substrate by flip-chip technology. Herein, gold or solder bumps are used between the LED and the substrate for connection so as to form a flip-chip LED.

Accordingly, the present invention can enhance the efficiency of heat dissipation of LEDs by means of the diamond layer with high thermal conductivity, and reduce the blockage for heat transfer caused by an adhesion layer used in prior art so as to enhance the efficiency of heat dissipation.

In addition, the lower surface of the LED of the present invention can further have a metal layer with reflecting property to enhance light extraction and improve the luminescence efficiency of products so as to simplify the process and enhance the performance and the stability of products.

Other objects, advantages, and novel features of the invention will become more apparent from the following detailed description when taken in conjunction with the accompanying drawings.

### BRIEF DESCRIPTION OF THE DRAWINGS

FIGS. 1A to 1D show cross-section views for manufacturing a conventional LED;

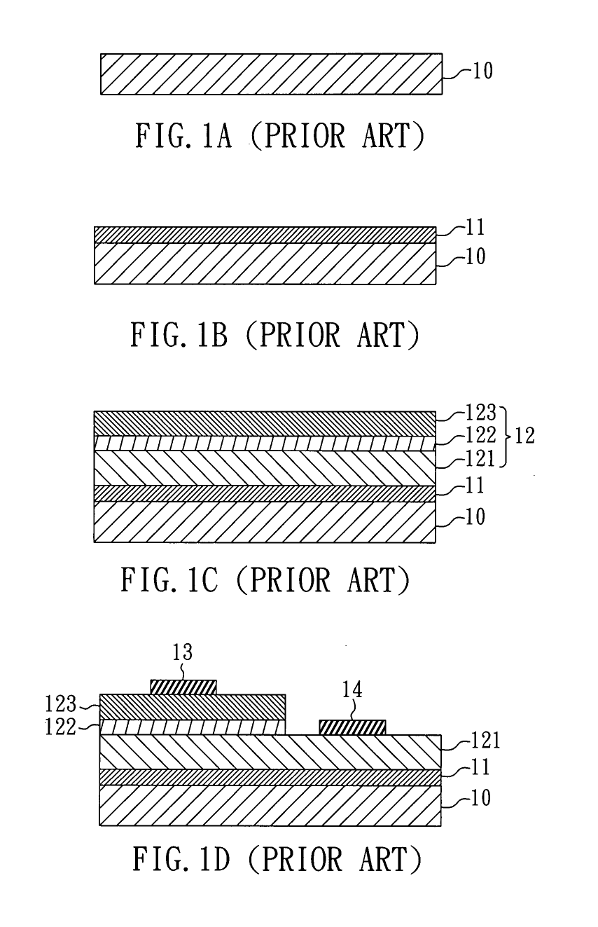

FIGS. 2A to 2E show cross-section views for manufacturing a vertical LED of a preferred embodiment of the present invention; and

FIGS. 3A to 3F show cross-section views for manufacturing a lateral LED of another preferred embodiment of the present invention.

### DETAILED DESCRIPTION OF THE PREFERRED EMBODIMENT

### Embodiment 1

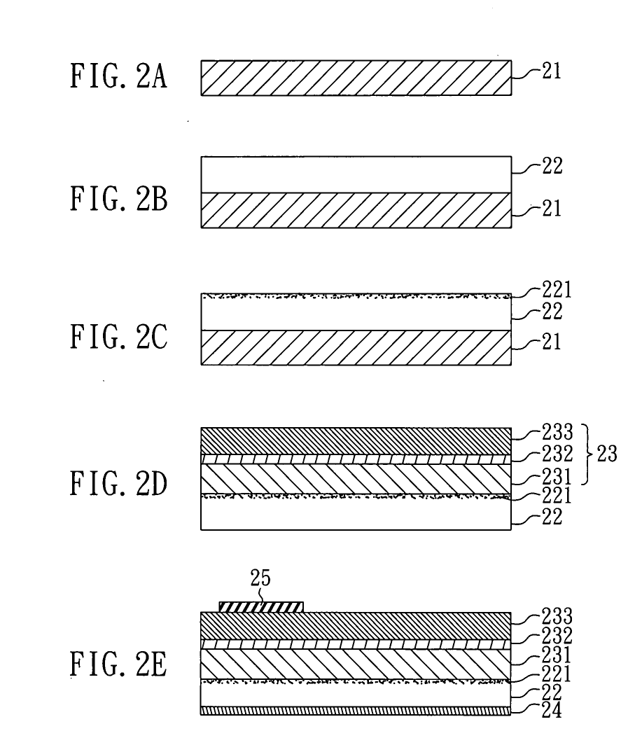

With reference to FIGS. 2A to 2E, a process is shown for manufacturing a vertical LED of a preferred embodiment of the present invention.

As shown in FIG. 2A, a substrate 21 is first provided. In the present embodiment, the substrate 21 is a silicon substrate. Then, as shown in FIG. 2B, a diamond layer 22 is formed on the surface of the substrate 21 by chemical vapor deposition method as a heat dissipation layer for enhancing the efficiency of heat dissipation. Herein, the material of the diamond layer 22 of the present embodiment is a conductive diamond. Subsequently, as shown in FIG. 2C, through ion implantation, the upper surface of the diamond layer 22 is doped with at least one element selected from the group consisting of elements of group II, elements of group III, elements of group IV, and elements of group V, and the element can react with diamond and exists in the semiconductor epitaxy layer (e.g. boron) so that a doping region 221 is formed on the upper surface of the diamond layer 22.

As shown in FIG. 2D, a semiconductor epitaxy layer 23 is bonded on the upper surface of the diamond layer 22 by high temperature bonding, and then the substrate 21 is removed. In the present embodiment, the semiconductor epitaxy layer 23 comprises a first semiconductor layer 231, an active layer 232, and a second semiconductor layer 233. Herein, the electrical property of the first semiconductor layer 231 is different from that of the second semiconductor layer 233. In the present embodiment, the substrate 21 is removed by physical cutting, and the semiconductor epitaxy layer 23 is formed by metal organic chemical vapor deposition.

Finally, as shown in FIG. 2E, a metal layer 24 is formed on the lower surface of the diamond layer 22 by sputtering, and a first electrode 25 is formed on the surface of the second semiconductor layer 233 of the semiconductor epitaxy layer 23 by sputtering so as to provide a vertical LED. In the present embodiment, the material of the metal layer 24 is gold, which can be as an electrode as well as a reflector so as to enhance light extraction and improve the luminescence efficiency.

Accordingly, the vertical LED provided by the present invention can enhance the efficiency of heat dissipation due to the presence of the diamond layer 22 with high thermal conductivity, and reduce blockage for light emission and heat transfer caused by a metal adhesion layer so as to enhance the efficiency of heat dissipation of LEDs. In addition, the metal layer 24 with reflecting property can enhance light extraction, and improve the luminescence efficiency, performance and stability of products.

### Embodiment 2

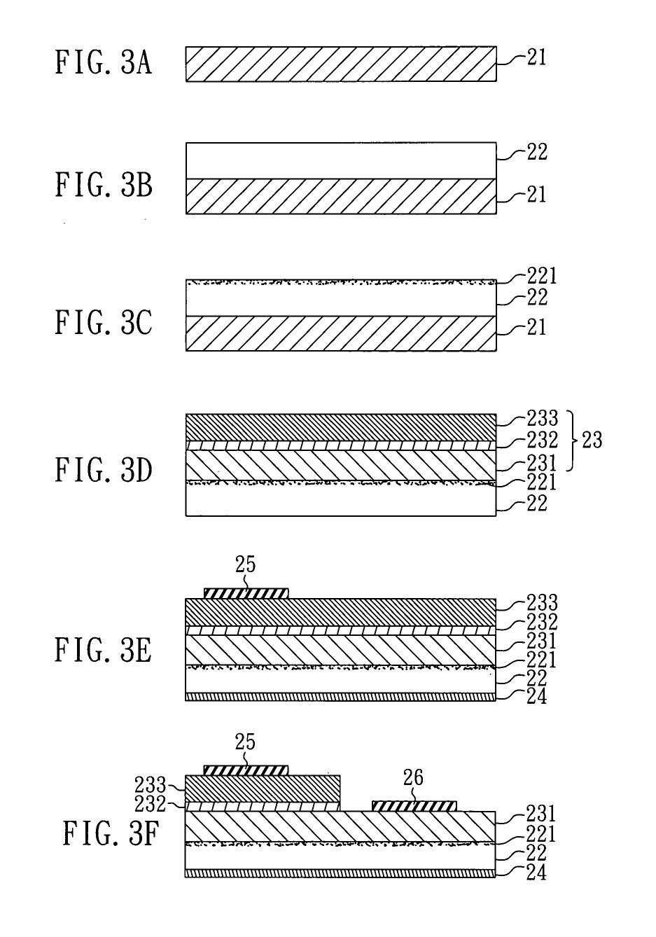

With reference to FIGS. 3A to 3F, a process is shown for manufacturing a lateral LED of another preferred embodiment of the present invention.

The process shown in FIGS. 3A to 3E of the present embodiment is the same as that shown in FIGS. 2A to 2E of Embodiment 1 except that the material of the diamond layer 22 used in the present embodiment is an insulated diamond and the process of the present embodiment further comprises a final step for forming a second electrode 26.

After the process shown in FIGS. 3A to 3E is performed, in reference to FIG. 3F, part of the second semiconductor layer 233 and part of the active layer 232 are removed to expose the first semiconductor layer 231 therebelow by etching, and a second electrode 26 is formed on the surface of the first semiconductor layer 231 by sputtering so as to accomplish a lateral LED.

Although the present invention has been explained in relation to its preferred embodiment, it is to be understood that many other possible modifications and variations can be made without departing from the spirit and scope of the invention as hereinafter claimed. In the present embodiment, the metal layer 24 can be a reflector.

The lateral LED of the present embodiment also exhibits the properties illustrated in Embodiment 1. That is the lateral LED can reduce blockage for light emission and heat transfer caused by a metal adhesion layer so as to enhance the efficiency of heat dissipation of LEDs, increase light extraction, and improve the luminescence efficiency, performance and stability.

What is claimed is:

1. A method for manufacturing a light emitting diode device, comprising following steps:
(A) providing a substrate;
(B) forming a diamond layer on the surface of the substrate;
(C) forming a doping region on the upper surface of the diamond layer;
(D) bonding a semiconductor epitaxy layer on the upper surface of the diamond layer, wherein the semiconductor epitaxy layer comprises a first semiconductor layer, an active layer, and a second semiconductor layer; and
(E) removing the substrate.

2. The method as claimed in claim 1, further comprising step (F) forming a metal layer on the lower surface of the diamond layer, and forming a first electrode on the surface of the semiconductor epitaxy layer after step (E).

3. The method as claimed in claim 2, wherein the material of the diamond layer is a conductive diamond.

4. The method as claimed in claim 2, further comprising step (G) removing part of the second semiconductor layer and part of the active layer to expose the first semiconductor layer therebelow, and forming a second electrode on the surface of the first semiconductor layer after step (F).

5. The method as claimed in claim 2, wherein in step (F), before the first electrode is formed on the surface of the semiconductor epitaxy layer, part of the second semiconductor layer and part of the active layer are removed to expose the first semiconductor layer therebelow, and a second electrode is formed on the surface of the first semiconductor layer.

6. The method as claimed in claim 4, or 5, wherein the material of the diamond layer is an insulated diamond, or a conductive diamond.

7. The method as claimed in claim 1, wherein the electrical property of the first semiconductor layer is different from that of the second semiconductor layer.

8. The method as claimed in claim 1, wherein the substrate is a silicon substrate, or a SiC substrate.

9. The method as claimed in claim 1, wherein the process for forming the semiconductor epitaxy layer in step (D) is performed by metal organic chemical vapor deposition, molecular beam epitaxy, liquid phase epitaxy, or vapor phase epitaxy.

10. The method as claimed in claim 1, wherein the process for forming the diamond layer in step (B) is performed by physical vapor deposition, or chemical vapor deposition.

11. The method as claimed in claim 1, wherein the process for forming the doping region in step (C) is performed by ion implantation, or plasma immersion ion implantation.

12. The method as claimed in claim 1, wherein the doping region comprises at least one element selected from the group consisting of elements of group II, elements of group III, elements of group IV, and elements of group V, and the element reacts with diamond and exists in the semiconductor epitaxy layer.

13. A light emitting diode device, which is formed by the method as claimed in claim 1.
